(19) United States
(12) Patent Application Publication
(10) Pub. No.: US 2007/0243673 A1
(43) Pub. Date: Oct. 18, 2007

(54) THIN-FILM TRANSISTOR ARRAY FOR LCD AND THE METHOD FOR MANUFACTURING THE SAME

(75) Inventor: Hen Ta KANG, Taichung City (TW)

Correspondence Address: LOWE HAUPTMAN HAM & BERNER, LLP, 1700 DIAGONAL ROAD, SUITE 300, ALEXANDRIA, VA, 22314, US

(73) Assignee: WINTEK CORPORATION, Taichung (TW)

(21) Appl. No.: 11/624,108

(22) Filed: Jan. 17, 2007

(30) Foreign Application Priority Data
Apr. 14, 2006 (TW) 095113316

(51) Int. Cl. H01L 21/84; H01L 21/00

(52) U.S. Cl. 438/158

(57) ABSTRACT

The present invention provides a thin-film transistor array, of which the units provide with a storage capacitor disposed in the thin-film transistor array and a protective layer of transparent conductive material covering the source/drain metal of the thin-film transistor array. The present invention also provides a method for manufacturing the thin-film transistor array, the method comprising three photomask processes, wherein the gate metal over the pixel electrode defined along with the gate is removed due to etch selectivity ratio; the active region of the thin-film transistor is defined by gray-tone mask; and the passivation film is defined through back-side exposure that is masked by the pattern of the gate metal region.

This application claims the priority benefit of Taiwan Patent Application Serial Number 095113316, filed Apr. 14, 2006, the full disclosure of which is incorporated herein by reference.

### BACKGROUND OF THE INVENTION

1. Field of the Invention

The present invention relates to a thin film transistor (TFT) array and the method for manufacturing the same and, more particularly, to a TFT array that is manufactured by a method including three photomask processes.

2. Description of Related Art

As the technology of electronic products progress, particularly for the prevalence of mobile electronic products in daily use, the demand increases day by day for displays with small size, light weight and low power consumption. Due to the advantages of low power consumption, low heat release and light weight, etc., liquid crystal displays (LCDs) are often used in such electronic products and even replace traditional cathode ray tube displays gradually. Moreover, as being of an active matrix design of low power consumption, high image quality and fast response, the thin film transistor liquid crystal display (TFT LCD) has become the main trend of the flat panel displays.

In the manufacturing processes for TFT arrays, application of the photomask has great influence on the production efficiency and manufacturing cost. Conventional TFTs have structures require 4 or 5 photomask processes to accomplish the manufacturing processes. For example, U.S. Pat. No. 4,624,737 requires at least 4 photomask processes. Taiwan Patent Publication No. 494266 discloses the typical structure a unit of amorphous silicon (a-Si) TFT which requires at least 5 photomask processes of back channel etch. For example, referring to FIG. 1, a first photomask process is first performed to deposit a layer of first metal on a substrate 20 so as to form a scan line region (not shown in the figure), a gate 30 and a first electrode 40 of the storage capacitor on the substrate 20. Subsequently, through a second photomask process, a silicon nitride layer 50, an a-Si layer 60 and a doped n⁺ a-Si layer 70 are deposited on the substrate 20 in sequence to form an island-like active region. Then, a layer of second metal is deposited, forming by a third photomask process, to form a data line region (not shown in the figure), a second electrode 80 of the storage capacitor, a source 90 and a drain 100. Then, a passivation layer 110 is deposited and etched through a forth photomask process so that a pixel electrode 120 to be formed next may be connected to the second electrode 80 of the storage capacitor. Finally, a fifth photomask process is performed in order to form the pixel electrode 120. Accordingly, each photomask process needs an independent photomask with which a photolithography process is performed.

However, since each photomask costs highly and each photolithography process includes photoresist coating, exposing, developing and photoresist removing, each addition of one photomask process would reduce the production efficiency and manufacturing cost and, therefore, the market power of the manufacturer. On the contrary, decrease of the number of photomasks for use may save the cost and shorten the procedure to increase the yield, thus raising the market power of the manufacturer.

On the other hand, adoption of different photomask process would lead to changes in the structure, thereby changes in the function of the TFTs produced. Thus, it is desirable to devise a way that the number of photomasks can be decreased while the TFTs obtained may function well.

### SUMMARY OF THE INVENTION

It is one object of the present invention to provide a TFT array and a method of manufacturing the same that includes three photomask processes.

It is another object of the present invention to provide a TFT array and a method of manufacturing the same that uses an etchant of high etch selectivity ratio in wet etching. The etchant etches a selected layer of metal and leaves transparent electrodes, thereby accomplishing a combination of two photomask processes as are followed in the prior art.

It is another object of the present invention to provide a TFT array and a method of manufacturing the same that devises a gray-tone mask process capable of reducing the thickness of the storage capacitors. The area of the storage capacitors may be reduced therefore, increasing the aperture ratio of pixel.

It is still another object of the present invention to provide a TFT array and a method of manufacturing the same that takes a way of back-side exposure to define the passivation layer. The layer of metal that has been patterned serves as a photomask hereby saving one more photomask process.

In order to achieve the objects described above, the present invention provides a method for manufacturing a TFT array. According to some embodiments of the invention, the method for manufacturing TFT arrays includes the following. First, a first transparent conducting material is deposited on a substrate and, then a first metal is deposited on the first transparent conducting material, wherein the first metal is suitable for a gate; and a first photolithography process is performed on the first transparent conducting material and the first metal with a first photomask, to form a gate, a pixel electrode, a scan line and a first electrode of the storage capacitor, among which each of the gate, the scan line and the first electrode of the storage capacitor consists of a first transparent conducting layer and a layer of first metal, while the pixel electrode is formed of the first transparent conducting layer which is covered with the layer of first metal. Second, a gate-insulating material, a semiconductor material and a doped semiconductor material are deposited sequentially; and a second photolithography process is performed on the three layers consisting of the gate-insulating material, the semiconductor material and the doped semiconductor material with a second photomask, which may be a gray-tone mask, to form an active region consisting of a gate-insulating layer, a layer of semiconductor and a layer of doped semiconductor, wherein the active region covers the gate and optionally the scan line and the first electrode of the storage capacitor, having a transporting channel formed inside the layer of semiconductor. Next, the portion of the layer of first metal on the pixel electrode is removed while the corresponding portion of the first transparent conducting layer is retained, wherein a process of wet etching may be adopted preferably with an etchant having low etch selectivity ratio to the layer of first metal and high etch selectivity ratio to the first transparent conducting layer. Next, a passivation material is deposited; and a process of back-side exposure is performed on the passivation material deposited, to form a passivation layer, wherein the layer of first metal that has been patterned serves as a photomask such that the passivation layer is right above the transporting channel and the scan line and that a dielectric region of the storage capacitor is formed due to the stacking of the passivation layer, the gate-insulating layer and the layer of semiconductor. Next, a second metal is deposited, which is suitable for a source/drain; and a third photolithography process is performed on the second metal deposited, with a third photomask, to form a source, a drain, a data line and a second electrode of the storage capacitor.

According to some embodiments of the present invention, the method for manufacturing a TFT array further includes: forming a first transparent conducting layer for the scan pad when the first photolithography process is performed on the first transparent conducting layer and the layer of first metal with a first photomask, wherein the first transparent conducting layer for the scan pad is outside of the active region and is overlain by the layer of first metal; removing the layer of first metal overlying the first transparent conducting layer for the scan pad when the portion of the layer of first metal on the pixel electrode is removed while the corresponding portion of the first transparent conducting layer is retained; and forming a scan pad when the third photolithography process is performed on the layer of second metal with the third photomask, wherein the scan pad consists of the first transparent conducting layer for the scan pad and the layer of second metal for the scan pad.

According to the present invention, in some embodiments of the TFT array on a substrate, each unit of the TFT array includes: a transistor, which includes a gate, a source, a drain and an active region, wherein the active region is formed of a gate-insulating material, a semiconductor material and a doped semiconductor material as being disposed sequentially from a substrate and defined thereafter, the gate is disposed on the substrate and is under the gate-insulating material, the source and the drain are disposed on the doped semiconductor material respectively and are electrically connected via a transporting channel, and the transporting channel is formed inside the semiconductor material; a pixel electrode, disposed on the substrate and electrically connected to the drain for the n-type TFT or to the source for the p-type TFT; a scan line, disposed on the substrate and under the gate-insulating material; a data line, disposed on a portion of the doped semiconductor material and vertically intersected with the scan line; a passivation material, disposed on the semiconductor material; and a storage capacitor, including a first electrode of the storage capacitor disposed on the substrate and under the gate-insulating material, a second electrode of the storage capacitor disposed on the passivation material, and a dielectric region of the storage capacitor between the first electrode of the storage capacitor and the second electrode of the storage capacitor, wherein the dielectric region of the storage capacitor is formed with the gate-insulting material, the semiconductor material and the passivation material stacked in sequence from the first to the second electrode of the storage capacitor.

Other objects, advantages, and novel features of the present invention will become more apparent from the following detailed description with certain embodiments in conjunction with the accompanying drawings.

### BRIEF DESCRIPTION OF THE DRAWINGS

FIG. 1 is a cross-section view of the unit structure of a conventional a-Si TFT array.

FIG. 2A-2F are cross-sectional views of the unit structure of the TFT array manufactured, each corresponding to in a process of the method according to one embodiment of the present invention.

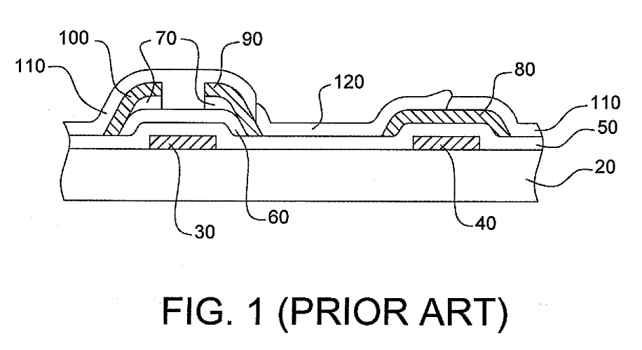

### DETAILED DESCRIPTION OF THE PREFERRED EMBODIMENT

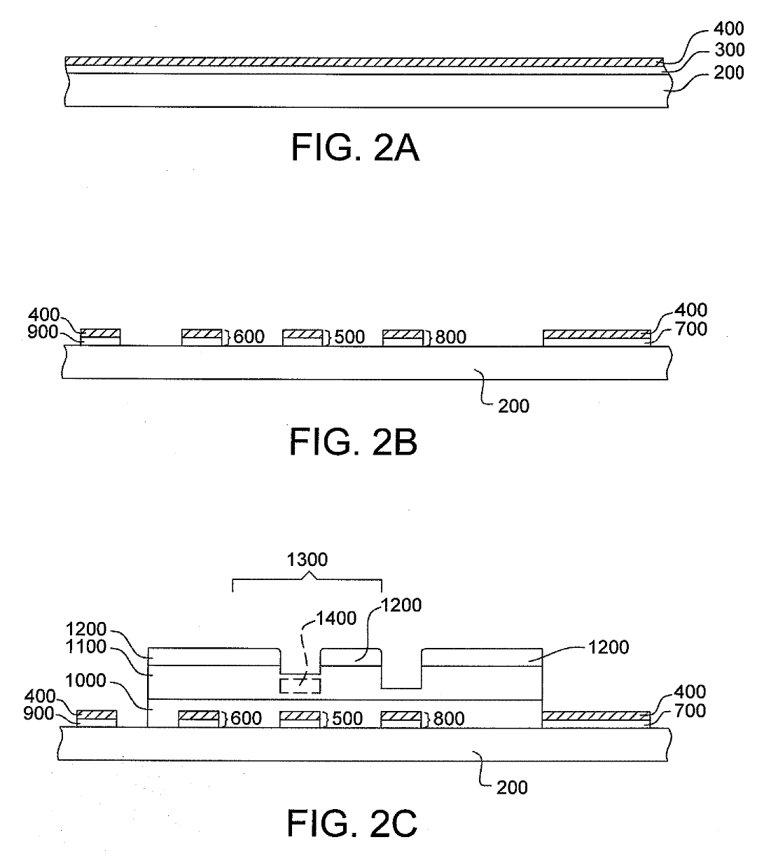

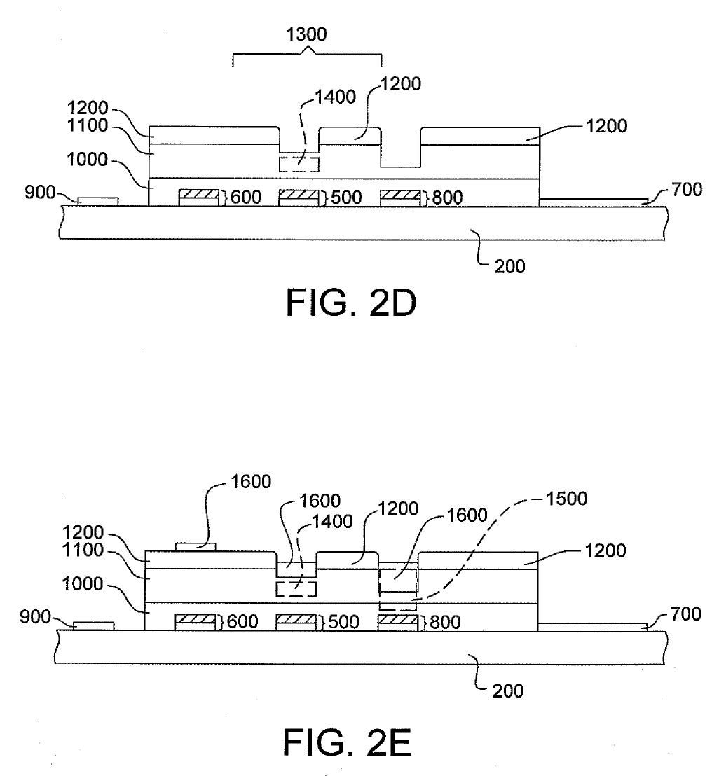

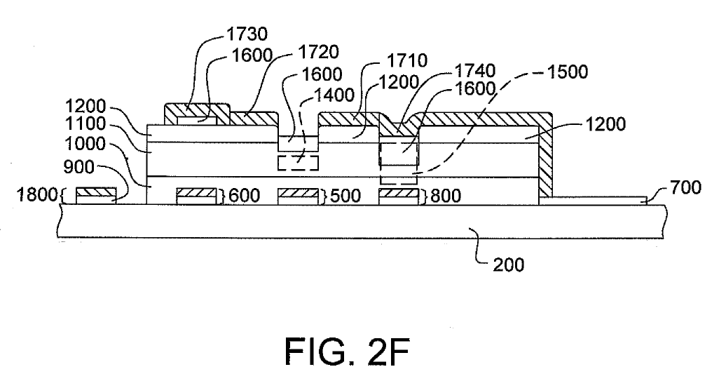

Referring to FIGS. 2A-2F, according to which one embodiment of the present invention will be described thoroughly. These drawings show the processes for manufacturing the TFT array in terms of a single unit.

Now referring to FIG. 2A, a first transparent conducting material 300, such as ITO (indium tin oxide) or IZO (indium zinc oxide) is deposited on a glass substrate 200. A first metal 400, such as multi-layer film of AlNd or Mo, is deposited on the first transparent conducting material 300.

Next, a first photolithography process is performed on the first transparent conducting material 300 and the first metal 400 with a first photomask. Dry etching or wet etching is used to form a gate 500, a scan line 600, a pixel electrode 700, a first electrode 800 of the storage capacitor and a first transparent conducting layer 900 for the scan pad on the substrate 200. Among them, each of the gate 500, the scan line 600 and the first electrode 800 of the storage capacitor consists of a first transparent conducting layer 300 and a layer of first metal 400, while each of the pixel electrode 700 and the first transparent conducting layer 900 for the scan pad is formed of the first transparent conducting layer 300 which is covered with the layer of first metal 400. The result is shown in FIG. 2B.

In the structure shown in FIG. 2B, a gate-insulating material, such as SiNₓ, a semiconductor material, i.e., a-Si, and a doped semiconductor material, i.e., n-type a-Si, are deposited in sequence. Then, a second photolithography process is performed on the three layers of materials described above with a second photomask, which is a gray-tone mask. Dry etching or wet etching is used to form an island-like active region 1300 consisting of a gate-insulating layer 1000, a layer of semiconductor 1100 and a layer of doped semiconductor 1200, as shown in FIG. 2C. Exposure through the gray-tone mask leads to a spatial variation of thickness after the process of etching. The photomask has differences of transparency and thus the photoresist undergoes various levels of exposure dose, which makes different thicknesses in the photoresist region when the process of development is done. According to the present invention, the various thicknesses fabricated over the structure depends on the design of the gray-tone mask. Moreover, the active region 1300 covers the gate 500, having a transporting channel 1400 formed inside the layer of semiconductor 1100. The result is shown in FIG. 2C.

According to the present invention, the portion of the layer of semiconductor 1100 on the first electrode 800 of the storage capacitor has a thickness defined in the process with gray-tone mask. Reducing the thickness of the layer of semiconductor 1100 by using a design of the gray-tone mask may increase the capacitance of the storage capacitor and, therefore decrease the area of the storage capacitor, thereby increasing the aperture ratio of the pixel.

As compared to dry etching, which can not control the etching level precisely, wet etching may remove selected layers of material by using an appropriate etchant of low etch selectivity ratio to those layers. This embodiment preferably adopts a process of wet etching, wherein a etchant is used that has low etch selectivity ratio to the layer of first metal 400 while has high etch selectivity ratio to the first transparent conducting layer 300. This will remove the portions of the layer of first metal 400 on the pixel electrode 700 and on the first transparent conducting layer 900 for the scan pad, as shown in FIG. 2C. The result is shown in FIG. 2D.

Referring to FIG. 2E, a passivation material, e.g., SiNₓ, is subsequently deposited. Then, a process of back-side exposure is performed on the passivation material so as to form a passivation layer 1600, wherein the layer of first metal that has been patterned serves as a photomask such that the passivation layer 1600 is right above the transporting channel 1400, or the gate 500, and the scan line 600 and that a dielectric region 1500 of the storage capacitor is formed due to the stacking of the passivation layer 1600, the gate-insulating layer 1000 and the layer of semiconductor 1100. In the way of the back-side exposure according to the present invention, the layer of first metal 400 comprised in the gate 500, in the scan line 600 and in the first electrode 800 of the storage capacitor functions as a photomask so that the passivation layer 1600 is formed right above the transporting channel 1400, the scan line 600 and the first electrode 800 of the storage capacitor. Thus, the present invention fulfills the purpose of protecting the TFT devices.

Next, referring to FIG. 2F, a second metal is deposited, which is suitable for a source/drain. A third photolithography process is performed on the second metal deposited with a third photomask to form a source 1710, a drain 1720, a data line 1730 and a second electrode 1740 of the storage capacitor. Moreover, a scan pad 1800 may be formed that consists of a layer of the second metal and the first transparent conducting layer 900 for the scan pad. The second metal includes, for example, a multi-layer film of AlNd or Mo, and a second transparent conducting layer (e.g., ITO or IZO covers and protects the multi-layer film against degradation).

According to the embodiments of the present invention, as shown in FIG. 2F for example, the TFT array is disposed on a substrate 200 and each unit of the TFT array includes: a transistor, a pixel electrode 700, a scan line 600, a data line 1730, a passivation layer 1600 and a storage capacitor. The transistor includes a gate 500, a source 1710, a drain 1720 and an active region 1300. The active region 1300 is formed by depositing a gate-insulating layer 1000, a layer of semiconductor 1100 and a layer of doped semiconductor 1200 in sequence on a substrate 200. The gate 500 is disposed on the substrate 200 and is under the gate-insulating layer 1000. The source 1710 and drain 1720 are disposed on the layer of doped semiconductor 1200 respectively and are electrically connected via a transporting channel 1400. The transporting channel 1400 is formed inside the layer of semiconductor 1100. The pixel electrode 700 is disposed on the substrate 200 and outside of the active region 1300, and electrically connected to the drain 1720 for the n-type TFT or to the source 1710 for the p-type TFT. The scan line 600 is disposed on the substrate 200 and under the gate-insulating layer 1000. The data line 1730 is disposed on a portion of the layer of doped semiconductor 1200 and vertically intersected with the scan line 600. The passivation layer 1600 is disposed on the layer of semiconductor 1100. The storage capacitor has a first electrode 800 of the storage capacitor disposed on the substrate 200 and under the gate-insulating layer 1000, a second electrode 1740 of the storage capacitor disposed on the passivation layer 1600, and a dielectric region 1500 of the storage capacitor interposed between the first electrode 800 of the storage capacitor and the second electrode 1740 of the storage capacitor, wherein the dielectric region 1500 of the storage capacitor is formed by stacking the gate-insulting layer 1000, the layer of semiconductor 1100 and the passivation layer 1600 in sequence from the first electrode 800 to the second electrode 1740 of the storage capacitor.

According to the embodiments of the present invention, as shown in FIG. 2F, each unit of the TFT array further comprises a scan pad 1800 disposed on the edge of the substrate 200. The scan pad 1800 includes a layer of second metal and the first transparent conducting layer 900 for the scan pad.

According to the embodiments of the present invention, the gate 500, the scan line 600 and the first electrode 800 of the storage capacitor are formed, respectively, with a first transparent conducting layer and a layer of first metal stacked in sequence on the substrate 200. The pixel electrode 700 is made of a first transparent conducting layer. Further, the scan pad 1800 is formed with the first transparent conducting layer and a second metal stacked in sequence on the substrate 200. The source 1710, the drain 1720, the data line 1730 and the second electrode 1740 of the storage capacitor are made of the second metal. The second metal includes, for example, a multi-layer film of metal, and a second transparent conducting layer covers the multi-layer film.

As described above, the TFT array and the method of manufacturing the same according to the present invention, which comprises only three photomask processes, can reduce the manufacturing cost, shorten the manufacturing procedure and increase the production efficiency and the market power. Additionally, the invention can utilize a gray-tone mask designed for reducing the thickness and, relatively, the area of the storage capacitor, thereby increasing the aperture ratio of each TFT. The invention can take a way of back-side exposure to make a passivation layer above at least the transporting channel in order that the TFT can be protected by the layer. Furthermore, a transparent conducting layer can be used for the source, the drain, the data line and the second electrode of the storage capacitor and/or the scan pad, so as to reduce the resistance effectively and to increase reliability and yield of the TFTs.

While the invention has been described in detail with certain preferable embodiments, this description is not intended to limit the invention for which other embodiments may be possibly employed. In particular, the invention is not only applicable to a-Si TFTs, but also to poly-silicon TFTs or any one that is based on suitable semiconductor material. It is to be understood that many other possible modifications and variations can be made by those skilled in the art without departing from the spirit and scope of the invention as hereinafter claimed.

What is claimed is:

1. A thin film transistor (TFT) array having a substrate and a plurality of TFT units, each TFT unit comprising:
a transistor having a gate, a source, a drain and an active region, the active region being formed by disposing a gate-insulating layer, a layer of semiconductor and a layer of doped semiconductor in sequence on a substrate;
a pixel electrode disposed on the substrate and electrically connected to the source or the drain;
a scan line disposed on the substrate and under the gate-insulating layer;
a data line disposed on a portion of the layer of doped semiconductor and in vertical intersection with the scan line;
a passivation layer disposed on the layer of semiconductor; and
a storage capacitor including a first electrode of the storage capacitor disposed on the substrate and under the gate-insulating layer, a second electrode of the storage capacitor disposed on the passivation layer, and a dielectric region of the storage capacitor interposed between the first electrode of the storage capacitor and the second electrode of the storage capacitor, wherein the dielectric region of the storage capacitor is formed by stacking the gate-insulting layer, the layer of semiconductor and the passivation layer in sequence from the first electrode to the second electrode of the storage capacitor.

2. The TFT array of claim 1, wherein the TFT unit further comprises a scan pad disposed on the edge of the substrate.

3. The TFT array of claim 1, wherein the gate is disposed on the substrate and under the gate-insulating layer, the source and drain are disposed on the layer of doped semiconductor respectively and are electrically connected via a transporting channel, the transporting channel is formed inside the layer of semiconductor.

4. The TFT array of claim 1, wherein the gate, scan line and first electrode of the storage capacitor are formed respectively with a first transparent conducting material and a first metal stacked in sequence on the substrate.

5. The TFT array of claim 2, wherein the pixel electrode is made of the first transparent conducting material.

6. The TFT array of claim 1, wherein the source, drain, data line and second electrode of the storage capacitor are made of a second metal.

7. The TFT array of claim 2, wherein the scan pad is formed with the first transparent conducting material and second metal stacked in sequence on the substrate.

8. A method for manufacturing a thin-film transistor (TFT) array having a substrate and a plurality of TFT units, the method comprising the processes of:
depositing a first transparent conducting material on the substrate and subsequently a first metal on the first transparent conducting material;
performing a first photolithography process on the first transparent conducting material and the first metal with a first photomask so as to form a gate, a scan line, a first electrode of the storage capacitor and a pixel electrode, wherein each of the gate, scan line and first electrode of the storage capacitor consists of a first transparent conducting layer and a layer of first metal, the pixel electrode is made of the first transparent conducting layer which is covered with the layer of first metal;
depositing a gate-insulating material, a semiconductor material and a doped semiconductor material in sequence;
performing a second photolithography process on the gate-insulating material, semiconductor material and doped semiconductor material with a second photomask so as to form an active region having a gate-insulating layer, a layer of semiconductor and a layer of doped semiconductor, wherein the active region covers the gate having a transporting channel formed inside the layer of semiconductor;
removing the portion of the layer of first metal on the pixel electrode;
depositing a passivation material;
performing a process of back-side exposure on the passivation material so as to form a passivation layer right above the transporting channel and scan line, wherein the passivation layer, gate-insulating layer and layer of semiconductor form a dielectric region of the storage capacitor;
depositing a second metal; and
performing a third photolithography process on the second metal with a third photomask so as to form a source, a drain, a data line and a second electrode of the storage capacitor.

9. The method of claim 8, wherein the process of performing a first photolithography process further comprises:
forming a first transparent conducting layer for the scan pad which is covered with the layer of first metal.

10. The method of claim 8, wherein the process of performing a second photolithography process uses a gray-tone mask as a second photomask.

11. The method of claim 8, wherein the process of performing a second photolithography process defines the thickness of the dielectric region of the storage capacitor.

12. The method of claim 9, wherein the process of removing the portion of the layer of first metal on the pixel electrode comprises:
removing the portion of the layer of first metal on the first transparent conducting layer for the scan pad.

13. The method of claim 8, wherein the process of removing the portion of the layer of first metal on the pixel electrode is processed by using an etchant having low etch selectivity ratio to the layer of first metal and high etch selectivity ratio to the first transparent conducting layer in the way of wet etching.

14. The method of claim 12, wherein the process of removing the portion of the layer of first metal on the pixel electrode is processed by using an etchant having low etch selectivity ratio to the layer of first metal and high etch selectivity ratio to the first transparent conducting layer in the way of wet etching.

15. The method of claim 9, wherein the process of performing a third photolithography process further comprises:
performing the third photolithography process on the portion of the second metal on the first transparent conducting layer for the scan pad with the third photomask so as to form a scan pad.
